(19) United States
(12) Patent Application Publication
(10) Pub. No.: US 2008/0145979 A1
(43) Pub. Date: Jun. 19, 2008

(54) METHOD FOR CHANGING CHARACTERISTIC OF THIN FILM TRANSISTOR BY STRAIN TECHNOLOGY

(75) Inventors: Ching-Fang HUANG, Taipei City (TW); Chee-Zxiang LIU, Taipei City (TW); Chee-Wee LIU, Taipei City (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: NATIONAL TAIWAN UNIVERSITY, Taipei (TW)

(21) Appl. No.: 11/951,808

(22) Filed: Dec. 6, 2007

(30) Foreign Application Priority Data
Dec. 13, 2006 (TW) 95146778

(51) Int. Cl. H01L 21/336

(52) U.S. Cl. 438/151; 257/E21.412

(57) ABSTRACT

A method for changing a characteristic of a thin film transistor (TFT) is provided. The method comprises the steps of (1) providing a substrate; (2) forming the TFT having a channel on the substrate; (3) providing a pressure source; and (4) causing the pressure source to form a strain on the channel. The method for changing the characteristic of the TFT can further raise the operational speed thereof.

### FIELD OF THE INVENTION

The present invention relates to a method for enhancing the mobility of the thin film transistors (TFTs), and more particularly to a method for enhancing the mobility of the TFTs by a strain technology.

### BACKGROUND OF THE INVENTION

In the current market of the planar display devices with the medium and the small dimensions, the active matrix liquid crystal displays has an extremely high market share, wherein TFT liquid crystal display panels are the key components in the electronic industries.

In the current commercial TFT liquid crystal display, the amorphous Si TFTs are commonly used, which are manufactured by a plasma-enhanced chemical vapor deposition (PECVD) process. Although the mobility of the amorphous Si TFTs is low, the current leakage thereof is relatively lower, and the amorphous Si TFTs are mainly used as the switch elements for pixels.

In recent years, the low temperature polycrystalline Si (LTPS) TFT liquid crystal display device becomes an extremely important technology. Since all kinds of electrical characteristics of LTPS TFTs are superior in those of the amorphous Si as well as the development of an excimer laser annealing becomes mature, the LTPS now becomes the most potential technology.

The LTPS TFTs have the advantages of low cost, high reliability and good performance. The electron mobility of the general amorphous Si TFTs are approximately 1 cm²/Vs, whereas the electron mobility of the LTPS TFTs could be up to 100˜200 cm²/Vs, which is several hundred times larger than that of the amorphous Si TFTs. Furthermore, the drive circuits of the TFTs could be simultaneously integrated on the glass substrate, which not only reduces the manufacturing costs and enhances the reliability, but also raises the aperture ratio of the LTPS.

In the prior strained-Si technology, it has been found from the studies regarding applying the strains on the metal-oxide-semiconductor field-effect transistor (MOSFET) that the drive current of elements and the operational speed thereof are effectively enhanced due to the increase of the carrier mobility.

In the TW patent publication No. 1237397, the method for increasing the speed of integrated circuits using the mechanical strained-Si is disclosed, where the operational speed of elements of MOSFET could be raised thereby. Uniaxial strains could be separated into one strain parallel with the current direction and the other strain perpendicular to the current direction, whereas the direction of biaxial strains are always the same at any angles and irrelevant to the current direction.

The present invention discloses an experimental method of the TFTs receiving the external strains. Based on the existing strained-Si technology, applying the strains on the TFTs will promote the generation of the strains within the channels of the elements, so that the TFTs could provide higher drive current and carrier mobility for those elements with bigger sizes.

From the above description, it is known that how to develop a TFT with an enhanced mobility has become a major problem to be solved. In order to overcome the drawbacks in the prior art, a TFT with the enhanced mobility by strain technology is provided. The particular design in the present invention not only solves the problems described above, but also is easy to be implemented. Thus, the invention has the utility for the industry.

### SUMMARY OF THE INVENTION

The present invention relates to a method for changing the characteristic of elements of a TFT and the operational speed thereof by a strain technology.

Despite most characteristics of the TFTs are similar to those of the traditional single crystalline Si MOSFET, there still exist some differences therebetween. Accordingly, the present invention focuses on applying the strain technology for increasing the carrier mobility in the MOSFET manufacturing process to the TFT field, so as to raise the operational speed of elements and the drive current of the TFT.

There are many implementing ways to utilize the strained-Si technology of the single crystalline Si, such as using Si/Ge as the materials of the drain and the source of the MOSFET, the high tensile/compressive stress nitride layer, the external mechanical strain and so on. Since the utilization of the external mechanical strain is more convenient for the operation as well as the cost thereof is extremely low, the present invention uses the external mechanical strain to increase the carrier mobility of the TFTs and change the electrical characteristics thereof. The other methods mentioned in the above could practically be used to manufacture the TFTs.

According to the above, the present invention provides a method for changing a characteristic of a thin film transistor (TFT), which comprises steps of: (1) providing a substrate; (2) forming the TFT having a channel on the substrate; (3) providing a pressure source; and (4) causing the pressure source to form a strain on the channel.

According to the mentioned method, the substrate is one selected from a group consisting of a glass substrate, a plastic substrate, a flexible substrate and a substrate made of a polymer material.

According to the mentioned method, the diameter and the shape of the substrate are arbitrary.

According to the mentioned method, the thickness of the substrate is ranged from 200 to 5000 μm.

According to the mentioned method, the TFT is one of an amorphous Si TFT and a low temperature polycrystalline Si TFT.

According to the mentioned method, the TFT has a source, a gate and a drain, each of which is one selected from a group consisting of a metal, a polycrystalline Si and a metal silicide with an arbitrary work function.

According to the mentioned method, the TFT comprises a gate insulator, and the equivalent oxide thickness of the gate insulator is ranged from 0.1 to 500 nm.

According to the mentioned method, the gate insulator of the TFT is one of a single oxide layer and a combination of multiple oxide layers.

According to the mentioned method, the channel length and width of the TFT are arbitrary.

According to the mentioned method, the TFT is one of an n-channel TFT and a p-channel TFT.

According to the mentioned method, while a direction of a stress provided by the pressure source to the TFT is a biaxial stress, an electric current direction of the TFT is not related to a direction of the biaxial stress.

According to the mentioned method, while a direction of a stress provided by the pressure source to the TFT is a uniaxial stress parallel with the channel, an electric current direction of the TFT is parallel with a direction of the strain.

According to the mentioned method, while a direction of a stress provided by the pressure source to the TFT is a uniaxial stress perpendicular to the channel, an electric current direction of the TFT is perpendicular to the direction of the strain.

According to the mentioned method, while a direction of a stress provided by the pressure source to the TFT is a uniaxial stress, the included angle between the directions of the electric current and the strain is arbitrary.

According to the mentioned method, the strain comes from one of a biaxial stress and a uniaxial stress.

According to the mentioned method, the strain is caused by one of a tensile stress and a compressive stress.

According to the mentioned method, the pressure source is one selected from a group consisting of a shallow trench isolation, a high tensile/compressive strain silicon nitride layer, an external mechanical strain, an island structure, a metal silicide and a hydrogen ion implantation.

According to the above, the present invention provides another method for changing a characteristic of a thin film transistor (TFT) and an operational speed thereof, which comprises steps of: (a) providing a substrate; (b) providing a pressure source on the substrate at a place on which the TFT is intended to be formed for providing a strain; and (c) forming the TFT having the strain on the substrate.

According to the mentioned method, the substrate is one selected from a group consisting of a glass substrate, a plastic substrate, a flexible substrate and a substrate made of a polymer material.

According to the mentioned method, the diameter and the shape of the substrate are arbitrary.

According to the mentioned method, the thickness of the substrate is ranged from 200 to 5000 μm.

According to the mentioned method, the TFT is one of an amorphous Si TFT and a low temperature polycrystalline Si TFT.

According to the mentioned method, the TFT has a source, a gate and a drain, each of which is one selected from a group consisting of a metal, a polycrystalline Si and a metal silicide with an arbitrary work function.

According to the mentioned method, the TFT comprises a gate insulator, and the equivalent oxide thickness of the gate insulator is ranged from 0.1 to 500 nm.

According to the mentioned method, the gate insulator of the TFT is one of a single oxide layer and a combination of multiple oxide layers.

According to the mentioned method, the channel length and width of the TFT are arbitrary.

According to the mentioned method, the TFT is one of an n-channel TFT and a p-channel TFT.

According to the mentioned method, while a direction of a stress provided by the pressure source to the TFT is a biaxial stress, an electric current direction of the TFT is not related to a direction of the biaxial stress.

According to the mentioned method, while a direction of a stress provided by the pressure source to the TFT is a uniaxial stress parallel with the channel, an electric current direction of the TFT is parallel with the direction of the strain.

According to the mentioned method, while a direction of a stress provided by the pressure source to the TFT is a uniaxial stress perpendicular to the channel, an electric current direction of the TFT is perpendicular to a direction of the strain.

According to the mentioned method, while a direction of a stress provided by the pressure source to the TFT is a uniaxial stress, the included angle between the directions of the electric current and the strain is arbitrary.

According to the mentioned method, the strain comes from one of a biaxial stress and a uniaxial stress.

According to the mentioned method, the strain is caused by one of a tensile stress and a compressive stress.

According to the mentioned method, the pressure source is one selected from a group consisting of a shallow trench isolation, a high tensile/compressive strain silicon nitride layer, an external mechanical strain, an island structure, a metal silicide and a hydrogen ion implantation.

According to the above, the present invention further provides a method for changing an operational speed of a thin film transistor (TFT), comprising steps of: (1) providing a substrate; (2) forming the TFT having a channel on the substrate; (3) providing a pressure source; and (4) causing the pressure source to form a strain on the TFT.

Preferably, the method is further used for changing the characteristic of the TFT, wherein the TFT is one of an n-channel TFT and a p-channel TFT.

The above aspects and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 is a schematic diagram of the TFT receiving the strain parallel thereto;

FIG. 2 is a schematic diagram of the TFT receiving the strain perpendicular thereto;

FIG. 3 is a lateral structural diagram of the TFT;

FIG. 4 is a schematic diagram of the present method for generating the strains by fixing the TFT and providing the pressure source thereon;

FIG. 5 is a variation diagram between the output current and voltage while the n-channel LTPS TFT is applied with an external tensile mechanical strain; and

FIG. 6 is a current variation diagram of the n-channel LTPS TFT while receiving the uniaxial (parallel or perpendicular) and the biaxial external tensile mechanical stress in the present method.

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

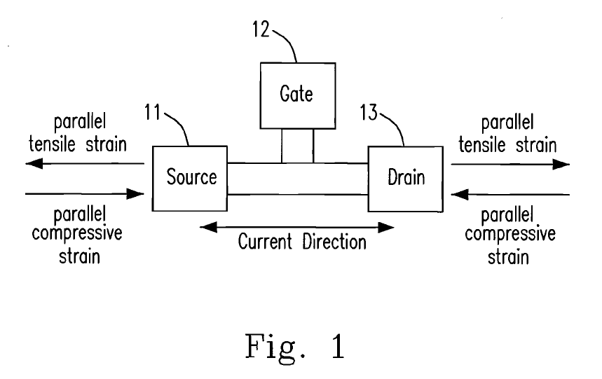

Please refer to FIG. 1, which shows a schematic diagram of the TFT receiving the strain parallel thereto. The TFT comprises a source 11, a gate 12 and a drain 13. A strain provided by a strain technology is applied to a channel beneath the gate 12, so as to enhance the drive current and the operational speed of the TFT. As illustrated in FIG. 1, the direction of the strain is parallel to that of the current.

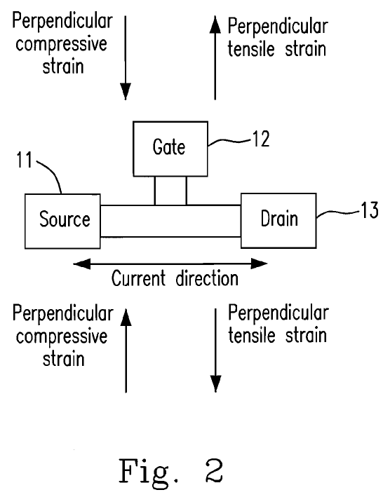

Please refer to FIG. 2, which shows a schematic diagram of the TFT receiving the strain perpendicular thereto. It is known from the illustration of FIG. 2 that the direction of the strain is perpendicular to that of the current. The strains as illustrated in FIGS. 1 and 2 could be tensile stresses or compressive stresses.

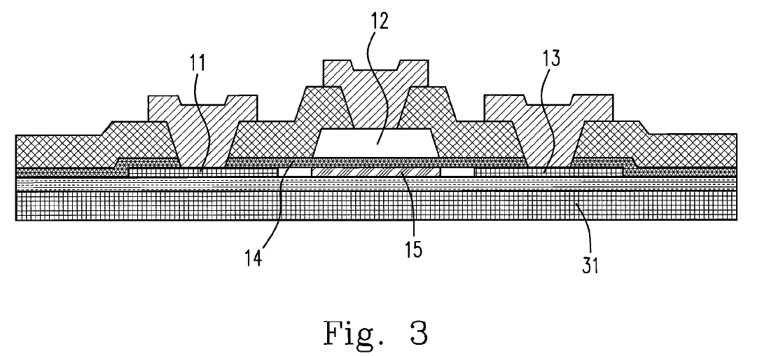

FIG. 3 is a lateral structural diagram of the TFT according to a preferred embodiment of the present invention, wherein an n-channel LTPS TFT is formed on a glass substrate 31. The TFT comprises the source 11, the gate 12, the drain 13, a gate insulator 14 and a channel region 15. In this embodiment, the glass substrate 31 is fixed on a mechanical device 40 which could give an external stress. The mechanical device 40 could apply a tensile stress on the channel of the TFT. That is, the pressure source in this embodiment is an external mechanical force. The TFT is an n-channel LTPS TFT and the strain is the tensile strain.

The material of the glass substrate 31 could be a glass substrate, a plastic substrate, a flexible substrate or any other substrate made of a polymer material. Through applying the uniaxial strain or the biaxial strain on the TFT, the carrier mobility of the channel of the TFT could be raised, so that the drive current of elements and the operational speed thereof are correspondingly enhanced.

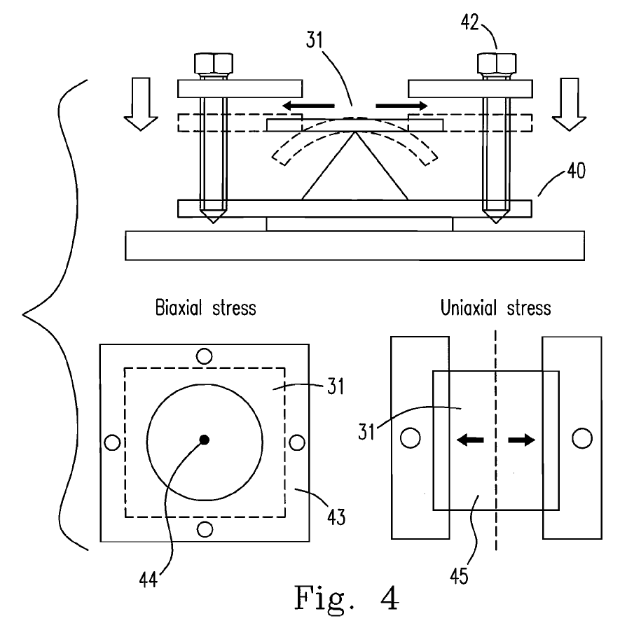

FIG. 4 depicts the mechanical device 40 which comprises a fixing screw 42. First, the glass substrate 31 is placed on the mechanical device 40, followed by fixing the glass substrate 31 to a square trench 43 with the fixing screws 42 to keep the glass substrate 31 in a horizontal state. If continuing to turn the fixing screw 42 downwards, the square trench 43 will be pressed downwards correspondingly. Therefore, the glass substrate 31 receives the tensile stress which results in curving the shape of the glass substrate 31. If the center of the mechanical 40 is a sharp cone 44, the glass substrate 31 fixed thereon will receive a biaxial tensile stress. If a triangle pillar 45 is disposed on the base of the mechanical device 40, the glass substrate 31 will receive a uniaxial stress after fixed on the mechanical device 40.

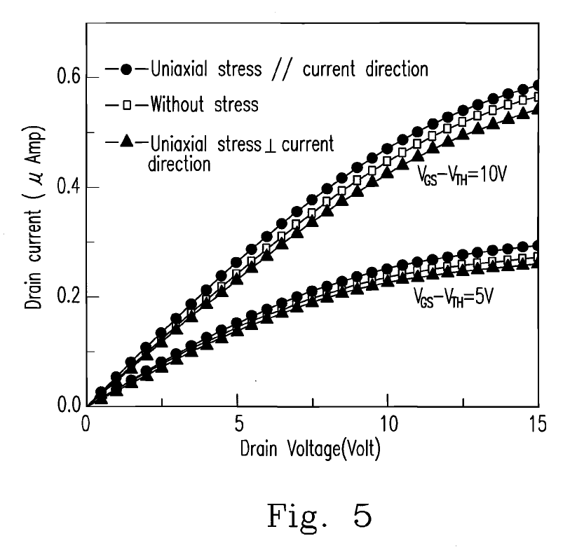

By means of applying the external mechanical force on the entire glass substrate 31, the carrier mobility of the n-channel LTPS TFT could be changed, and the drive current and the operational speed thereof could be enhanced correspondingly. FIG. 5 depicts the relationship between the output current and the output voltage of the n-channel LTPS TFT. It is known from the illustration of FIG. 5 that the drive current will be increased while the direction of the applied uniaxial stress is parallel to the current direction; that is to say, the operational speed of the TFT is also increased. Hence, the pressure source of the present invention indeed enhances the carrier mobility of the TFT, thereby increasing the operational speed of elements. Please refer to FIG. 5 again. The drive current of the n-channel polycrystalline Si TFT is unable to be increased while the n-channel polycrystalline Si TFT receives the uniaxial stress in the perpendicular direction or the biaxial stress, whereas the current variation ratio of the p-channel polycrystalline Si TFT is dependent on the intensity of the external strain while the p-channel polycrystalline Si TFT receives the uniaxial stress in the perpendicular direction or the biaxial stress. Therefore, the present invention provides a method for increasing the current of the TFT by means of applying the uniaxial or the biaxial stress.

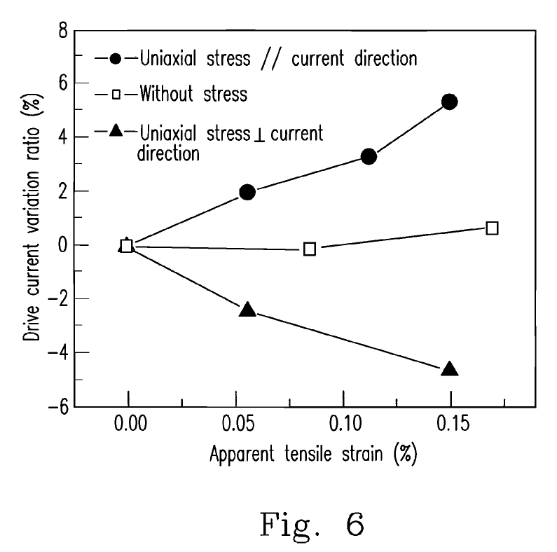

Please refer to FIG. 6, which shows the current variation diagram while the n-channel LTPS TFT receives the external, tensile, mechanical, uniaxial and biaxial strains. According to the experimental results as illustrated in FIG. 6, it is proved that the resultant drive current variation ratio displays linearly if the n-channel LTPS TFT continues to receive an external linear strain. In FIG. 6, the x-axis represents an apparent tensile strain and the y-axis represents a current variation ratio. In the experiments, the apparent tensile strain is an external strain, but the real tensile strain applied on the TFT is lower than the apparent tensile strain since the TFT will release the partial strain due to the existence of grain boundaries in the polycrystalline Si layer. It is also observed in FIG. 6 that the drive current of the n-channel polycrystalline Si TFT becomes lower while a uniaxial stress in the direction perpendicular to the current direction is provided.

Based on the above, the present invention applies the strain technology for increasing the carrier mobility in the MOSFET manufacturing process to the TFT field, so as to enhance the operational speed of elements of the TFTs and raise the drive current thereof. Accordingly, the present invention can effectively solve the problems and drawbacks in the prior art, and thus it fits the demand of the industry and is industrially valuable.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A method for changing a characteristic of a thin film transistor (TFT), comprising steps of:
(1) providing a substrate;
(2) forming the TFT having a channel on the substrate;
(3) providing a pressure source; and
(4) causing the pressure source to form a strain on the channel.

2. A method as claimed in claim 1, wherein the substrate is one selected from a group consisting of a glass substrate, a plastic substrate, a flexible substrate and a substrate made of a polymer material.

3. A method as claimed in claim 1, wherein a thickness of the substrate is ranged from 200 to 5000 ρm.

4. A method as claimed in claim 1, wherein the TFT is one of an amorphous Si TFT and a low temperature polycrystalline Si TFT.

5. A method as claimed in claim 1, wherein the TFT has a source, a gate and a drain, each of which is one selected from a group consisting of a metal, a polycrystalline Si and a metal silicide with an arbitrary work function.

6. A method as claimed in claim 1, wherein the width and length of the TFT are arbitrary.

7. A method as claimed in claim 1, wherein the TFT comprises a gate insulator with a thickness of the gate insulator being ranged from 0.1 to 500 nm, and the gate insulator of the TFT is one of a single oxide layer and a combination of multiple oxide layers.

8. A method as claimed in claim 1 further used for changing an operational speed of the TFT, wherein the TFT is one of an n-channel TFT and a p-channel TFT.

9. A method as claimed in claim 1, wherein while a direction of a stress provided by the pressure source to the TFT is a biaxial stress, an electric current direction of the TFT is not related to a direction of the biaxial stress.

10. A method as claimed in claim 1, wherein while a direction of a stress provided by the pressure source to the TFT is a uniaxial stress parallel with the channel, an electric current direction of the TFT is parallel with a direction of the strain; and while a direction of a stress provided by the pressure source to the TFT is a uniaxial stress perpendicular to the channel, an electric current direction of the TFT is perpendicular to the direction of the strain.

11. A method as claimed in claim 1, wherein while a direction of a stress provided by the pressure source to the TFT is a uniaxial stress, the included angle between the directions of the electric current and the strain is arbitrary.

12. A method as claimed in claim 1, wherein the strain comes from one of a biaxial stress and a uniaxial stress.

13. A method as claimed in claim 1, wherein the strain is caused by one of a tensile stress and a compressive stress.

14. A method as claimed in claim 1, wherein the pressure source is one selected from a group consisting of a shallow trench isolation, a high tensile/compressive strain silicon nitride layer, an external mechanical strain, an island structure, a metal silicide and a hydrogen ion implantation.

15. A method for changing a characteristic of a thin film transistor (TFT) and an operational speed thereof, comprising steps of:
(1) providing a substrate;
(2) providing a pressure source on the substrate at a place on which the TFT is intended to be formed for providing a strain; and
(3) forming the TFT having the strain on the substrate.

16. A method as claimed in claim 15, wherein the substrate is one selected from a group consisting of a glass substrate, a plastic substrate, a flexible substrate and a substrate made of a polymer material.

17. A method as claimed in claim 15, wherein a thickness of the substrate is ranged from 200 to 5000 μm.

18. A method as claimed in claim 15, wherein the TFT is one of an amorphous Si TFT and a low temperature polycrystalline Si TFT.

19. A method as claimed in claim 15, wherein the TFT has a source, a gate and a drain, each of which is one selected from a group consisting of a metal, a polycrystalline Si and a metal silicide with an arbitrary work function.

20. A method as claimed in claim 15, wherein the TFT further comprises a gate insulator with a thickness of the gate insulator being ranged from 0.1 to 500 nm, and the gate insulator of the TFT is one of a single oxide layer and a combination of multiple oxide layers.

21. A method for changing an operational speed of a thin film transistor (TFT), comprising steps of:
(1) providing a substrate;
(2) forming the TFT having a channel on the substrate;
(3) providing a pressure source; and
(4) causing the pressure source to form a strain on the TFT.

22. A method as claimed in claim 21 further used for changing a characteristic of the TFT, wherein the TFT is one of an n-channel TFT and a p-channel TFT.
